(19) United States
(12) Patent Application Publication
(10) Pub. No.: US 2006/0026480 A1
(43) Pub. Date: Feb. 2, 2006

(54) Method and apparatus for generating test signals

(76) Inventor: Andreas Logisch, Munchen (DE)

Correspondence Address: JENKINS, WILSON & TAYLOR, P. A., 3100 TOWER BLVD, SUITE 1400, DURHAM, NC, 27707, US

(21) Appl. No.: 11/187,739

(22) Filed: Jul. 22, 2005

(30) Foreign Application Priority Data
Jul. 30, 2004 (DE) 102004036957.7-35

(51) Int. Cl. G01R 31/28; G06F 11/00

(52) U.S. Cl. 714/738

(57) ABSTRACT

Method for the generation of test signals (TS) by means of a test signal generator to a component (6) to be tested,

the test signal generator generating rising and falling signal edges which are in each case assigned to successive time windows (TS1-TSN) with predetermined time durations (T0), having the following method steps of:

determining a command sequence frequency (BAF) of the component (6) to be tested;
allocating instants (TS1U, . . . TSNU) for rising signal edges and allocating instants (TS1D . . . TSND) for falling signal edges for the successive time windows (TS1-TSN), the instants for the rising or falling signal edges (TS1D, . . . TSND, TS1U-TSNU) that are allocated to a respective time window being allocated in each case into the time range of the time window if the command sequence frequency (BAF) is lower than a limiting frequency (GF) of the test signal generator, the said limiting frequency being determined by the predetermined time duration (T0), or allocating at least one instant (TS1U, . . . TSNU) for a rising signal edge and allocating at least one instant (TS1D, . . . TSND) for a falling signal edge for the successive time windows (TS1-TSN), at least one allocated instant (TS1U, . . . TSND) for a rising or falling signal edge being allocated into a time range of one of the following time windows if the command sequence frequency (BAF) is higher than the limiting frequency (GF) of the test signal generator;
generating the test signal (TS) with the respective signal edges at the allocated instants (TS1U, . . . TSND) and applying the corresponding test signal (TS) to the component (6) to be tested.

The present invention relates to a method for generating test signals having a particularly high sequential frequency of rising and/or falling signal edges. The invention furthermore relates to a test system for carrying out this method.

Particular sequences of test signals are required in particular for memory test systems. In this case, a series of signal sequences corresponding to write and read operations are coupled into a component to be tested, e.g. a memory chip. The test system then compares the data read with the known data written in and decides about the quality of the tested component.

Each test system can generate signals with a maximum frequency, its limiting frequency. In general, the test signals are composed of rising and falling signal edges set at specific instants in a test sequence.

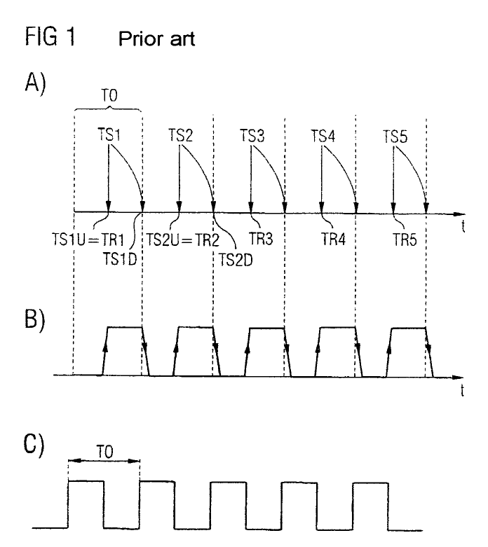

FIG. 1 illustrates the generation of a regular test clock signal according to the prior art. A test run is organized in the form of successive time windows TS1-TS5, each time window TS1-TS5 having a predetermined time duration T0. In a manner governed by the construction, in the case of a memory tester each time window TS1-TS5 can be allocated in each case an instant TS1U, TS2U for a rising signal edge and an instant TS1D, TS2D for a falling signal edge. This is illustrated by allocation arrows in FIG. 1 (A).

In FIG. 1, over a time period covered by the time windows TS1-TS5, a periodic signal is provided which in each case has a rising signal edge in the centre of the time windows TS1-TS5 as reference instant TR1-TR5 and a falling signal edge at the end of the time windows TS1-TS5. FIG. 1 (B) schematically shows the resulting signal.

FIG. 1 (C) illustrates an idealized signal profile, the test signal having a period T0 predetermined by the time duration T0 of each time window TS1-TS5. In the prior art, the highest achievable frequency GF of the test signal generator is thus GF=1/T0.

Memory test systems are relatively long-lived apparatuses in comparison with the components or memory chips to be tested. Whereas memory testers are used over decades, the operating frequency or clock rate of memory chips increases at time intervals of a few years. In order to be able to practically test new memory chips, command sequence frequencies, i.e. sequences of successive rising and falling signal edges, are often required in the case of which rising signal edges rapidly succeed one another within a few nanoseconds. If the command sequence frequency of the component to be tested exceeds the limiting frequency of the test signal generator, it has been necessary in the past to use a new memory tester with a higher limiting frequency or maximum test frequency. This requires either the procurement of newer test systems or at least the transfer of the components to be tested into a faster test system for the test sequences of the memory chip to be tested that are required for a higher command sequence frequency.

Therefore, it is an object of the present invention to provide a method and an apparatus for the generation of test signal, the frequency of a sequence of pairs of rising and falling signal edges lying above the limiting frequency of the test signal generator used.

This object is achieved by means of a method having the steps of Patent claim 1 and also a test system for carrying out the method having the features of Patent claim 14.

Accordingly, the method according to the invention for the generation of test signals by means of a test signal generator to a component to be tested,

the test signal generator generating rising and falling signal edges which are in each case assigned to successive time windows with predetermined time durations, provides the following method steps of:

(a) determining a command sequence frequency of the component to be tested;
(b1) allocating instants for rising signal edges and allocating instants for falling signal edges for the successive time windows, the instants for the rising or falling signal edges that are allocated to a respective time window being allocated in each case into the time range of the time window if the command sequence frequency is lower than a limiting frequency of the test signal generator, the said limiting frequency being determined by the predetermined time duration, or
(b2) allocating at least one instant for a rising signal edge and allocating at least one instant for a falling signal edge for the successive time windows, at least one allocated instant for a rising or falling signal edge being allocated into a time range of one of the following time windows if the command sequence frequency is higher than the limiting frequency of the test signal generator.
(c) generating the test signal with the respective signal edges at the allocated instants and applying the corresponding test signal to the component to be tested.

The idea according to the invention essentially consists in arranging some instants for rising and falling signal edges at instants which do not lie in the time range of the respective time window to which the instants are allocated, but rather are disposed temporally later. This makes it possible, according to the invention, to generate command sequence frequencies, that is to say sequences of rising and falling signal edges, which are significantly higher than the limiting frequency of the test signal generator. The method according to the invention makes it possible to generate a plurality of rising and falling signal edges within the predetermined time duration of a time window.

In an advantageous manner, the instants for the signal edges which are assigned to a first number of successive time windows are allocated such that the instants lie in a time range of a second number of successive time windows which follows the first number of time windows. This advantageously means that few rising and falling signal edges lie in the first number of time windows in comparison with the limiting frequency, and rising and falling signal edges are generated in a high frequency sequence in the second number of time windows, or in the time range defined by the number of time windows.

In an advantageous manner, method step (b2) comprises the substeps:
(b21) defining a respective reference instant for each time window;
(b22) defining a delay time;
(b23) selecting a number N of successive time windows;
(b24) allocating the instants of the rising signal edges, which are assigned to the selected number of successive time windows,
   the instant for the rising signal edge assigned to the K-th time window in each case being positively shifted by a delay time (1+N−K)ΔT relative to the respective reference instant of the K-th time window.

In an advantageous manner, the selected delay time ΔT is the difference between the corresponding periods of the limiting frequency and the command sequence frequency. The additional method steps make it possible, over the time range NΔT covered by the successive time windows, to provide a command sequence frequency that is higher than the limiting frequency of the test signal generator. This is highly advantageous if, for example in a memory test method, e.g. for reading or writing, a sequence of rapidly successive clock edges are required as a test clock signal.

In an advantageous manner, before the N selected time windows, provision is made of a preceding time window which is assigned a rising signal edge, the instant allocated to the rising signal edge corresponding to the reference instant of the preceding time window.

Furthermore, an N+1 test time window is advantageously provided, which is assigned a rising signal edge, the instant allocated to the rising signal edge corresponding to the reference instant of the N+1-th time window. The reference instants are advantageously provided in the centre of the time range of the respective time windows. The instants of the falling signal edges are preferably allocated such that a rising and a falling signal edge which are assigned to the same time window in each case succeed one another.

The time windows are preferably arranged periodically. This modification of the method according to the invention for the generation of test signals is particularly suitable for use in memory systems designed for cyclic tests or recurring test patterns.

The test system according to the invention for carrying out the method according to the invention provides (a) a clock generator (2) for generating an internal clock signal, (b) a signal edge generating device for generating rising and falling signal edges in a manner dependent on sequence control signals and for coupling into a component to be tested, (c) sequence control logic for generating the sequence control signals, which is clocked by the internal clock signal and (d) evaluation logic for reading out and evaluating signals of the component to be tested.

Preferably the sequence control logic is embodied in programmable fashion and the component to be tested is a memory component. It is particularly simple to use the method according to the invention in the case of programmable sequence control logics.

Further advantageous refinements are the subject-matter of the subclaims and of the following description of the exemplary embodiments. The invention is explained below on the basis of exemplary embodiments with reference to the schematic figures. In the figures, unless specified otherwise, identical reference symbols are allocated to identical or functionally identical elements.

In this case:

FIG. 1 shows a method for the generation of test signals according to the prior art,

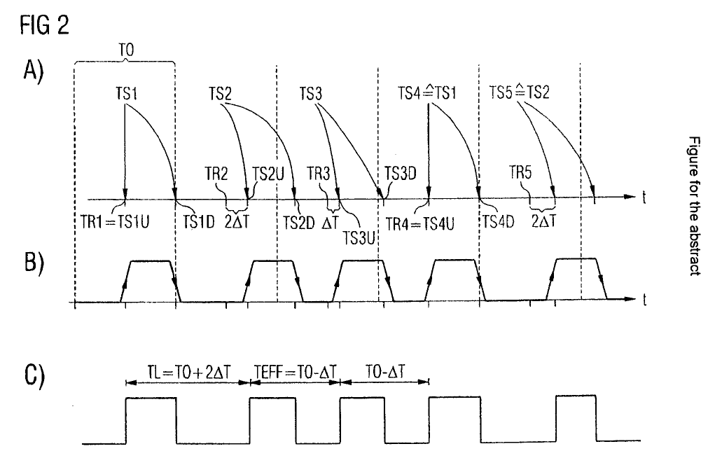

FIG. 2 shows the method for the generation of test signals according to the invention,

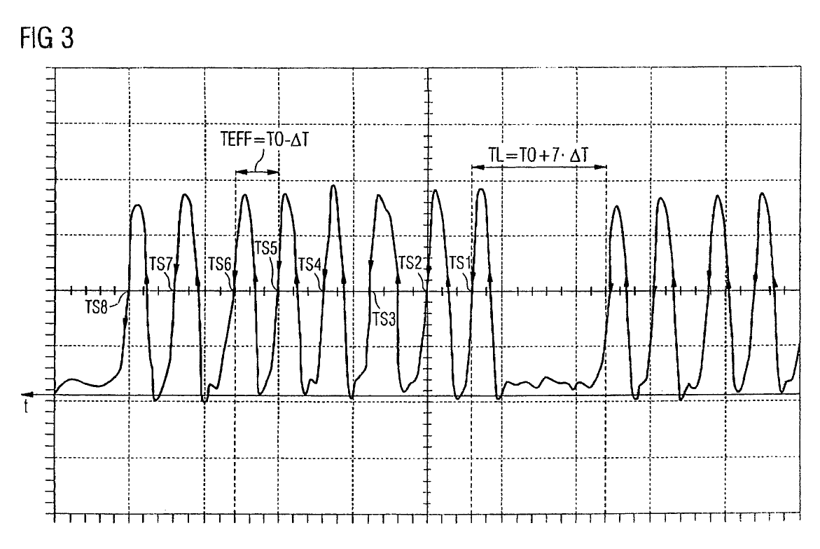

FIG. 3 shows a test signal generated according to the invention,

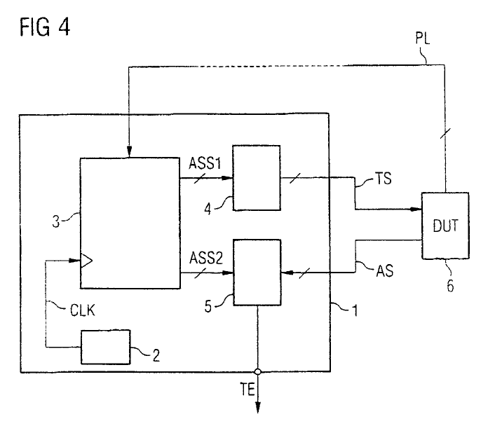

FIG. 4 shows a test system according to the invention, and

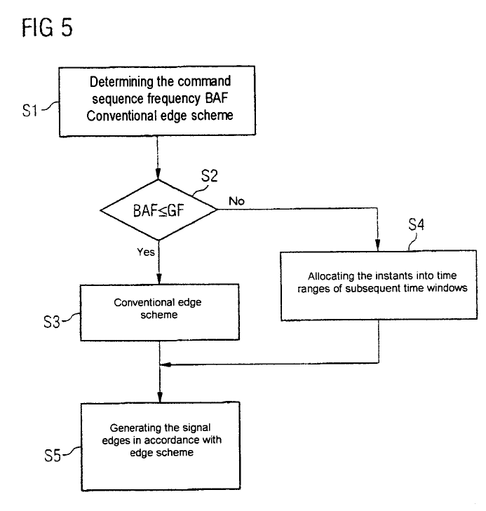

FIG. 5 shows a flow diagram of the method according to the invention.

FIG. 2 shows a test signal profile according to the invention for the generation of command sequence frequencies having periods reduced by a delay time ΔT relative to the limiting frequency of the test signal generator used.

The row (A) shows the sequence of time windows TS1-TS5 and the corresponding allocated instants TS1U, TS1D, TS2U, TS2D, TS3U, TS3D, TS4U, TS4D for rising and falling signal edges. The allocation is indicated by the arrows in FIG. 2 (A). In each time window TS1-TS2, a reference instant TR1-TR5 is defined in the centre of the respective time window TS1-TS5.

The instant for the rising signal edge which is allocated to the first time window TS1 occurs upon the reference instant TR1 of the first time window TS1. The instant for the falling signal edge TS1D for the first time window TS1 is allocated to the end of the first time window TS1, that is to say is effected after the time t=T0. The instant for the rising signal edge TS2U for the second time window TS2 is shifted positively by 2*ΔT relative to the reference instant TR2 of the second time window TS2. The instant for the following positive signal edge TS3U for the third time window TS3 is shifted positively by ΔT relative to the reference instant TR3 of the third time window TS3, that is to say is effected at the instant 2.5 T0+T0/2+ΔT. The instant for the falling signal edge TS2D which is allocated to the second time window TS2 lies between the instants for the rising signal edges TS2U, TS3U which are allocated to the second and third time window TS2, TS3. The instant for the rising signal edge TS4U which is allocated to the fourth time window TS4 is effected according to the same scheme as for the first time window TS1, namely at the reference instant TR4. The instant for the falling signal edge for the fourth time window TS4 is effected at the end of the fourth time window TS4, that is to say at the time 4T0.

Signal sequences or command sequences with frequencies lying above the limiting frequency GF=1/T0 are effectively achieved during the time ranges in which the time windows TS2, TS3 and TS4 lie. The correspondingly generated test signal is illustrated in FIG. 2 (B), and FIG. 2 (C) illustrates the idealized test signal with the same time structure. In the case of the example chosen here, a test signal is generated which has an effective clock signal with a clock period TEFF=T0−ΔT in the time range between T0 and 3T0. These two high-frequency clock pulses are preceded by a clock pulse with a lengthened clock period TL=T0+2*ΔT.

FIG. 3 illustrates a second example of a test signal generated according to the invention, such as may be generated for example by means of a T5585 test system from the company Advantest, which has a limiting frequency of 250 MHz. This corresponds to a minimum time duration T0=4 ns.

FIG. 3 does not illustrate the assignment of the individual instants for the rising and falling signal edges, but rather only the signal profile and the edges or signals generated by the assigned instants at the time windows TS1-TS8. By means of the time window TS1, firstly a very long clock pulse with a temporal interval of T0+7ΔT between two falling clock edges is generated, and then over a time duration of 7(T0−ΔT) a clock-like test signal with the period TEFF=T0−ΔT.

Based on a time duration T0=4 ns per time window, the first time range TL=T0+7ΔT=8.9 ns given a delay time of ΔT=0.7 ns. A sequence of rising and falling clock edges TS2-TS8 subsequently results, the effective rate or the effective clock period TEFF=3.3 ns ensuing. This corresponds to a frequency of 300 MHz, which is increased by 50 MHz relative to the limiting frequency of the test system or the test signal generator.

The method according to the invention thus makes it possible for example to generate command sequence frequencies far above the limiting frequency of the test signal generator used. By way of example, the first pair of rising and falling clock edges, having a large interval between them, may represent a start command for reading from or writing to a memory chip to be tested. The then rapid sequence with a short temporal interval between rising and falling clock edges can then be used as a command sequence for writing in data or data themselves to the memory.

FIG. 4 shows a test system according to the invention for carrying out the method according to the invention.

A memory tester 1 is provided, having a clock generator 2 for generating an internal clock signal CLK, which is coupled to a sequence control logic 3. The sequence control logic 3 is coupled via control lines to a signal edge generating device 4 and an evaluation logic 5. Depending on sequence control signals ASS1, the signal edge generating device 4 supplies test signal sequences TS to a component 6 to be tested. In reaction to the test signals TS, the component 6 to be tested outputs response signals AS which are coupled into the evaluation logic 5. The component 6 to be tested is furthermore coupled to the sequence control logic 3 via test lines PL.

The sequence control logic 3 coordinates the signal edge generating device 4 and the evaluation logic 5 by generating sequence control signals ASS1, ASS2. The evaluation logic 5 compares the response signals AS of the component 6 or memory to be tested with expected responses and outputs a test result TE over the course of the test method.

FIG. 5 schematically shows the sequence of the method according to the invention for the generation of test signals in the test system according to the invention as illustrated in FIG. 4.

By means of the test line PL, the sequence control logic 3 ascertains a command sequence frequency of the memory 6 to be tested. This is effected in the first step S1.

This may be done for example by reading the characteristic data of the corresponding memory. By way of example, it is possible to provide a DDR2-RAM as component to be tested, the characteristic data of which have been programmed by the sequence control logic, and which then identifies the corresponding temporal specifications for the chip.

In step S2, the sequence control logic 3 decides whether the command sequence frequency BAF required by the memory component to be tested is greater or less than the nominal limiting frequency GF. If the limiting frequency GF is higher than the command sequence frequency, the sequence control logic 3 can use a conventional scheme according to the prior art, for example as illustrated in FIG. 1 (step S3).

If the command sequence frequency BAF required by the memory component 6 to be tested lies above the limiting frequency GF, the allocation of the instants for rising and falling clock edges takes place according to the allocation according to the invention into subsequent time ranges of subsequent time windows (step S4). The sequence control logic 3 thus sends sequence control signals ASS1, ASS2 to the signal edge generating device 4 and the evaluation logic 5. The duration of the time windows T0 is defined by the frequency of the internal clock signal CLK. At the instants defined by the sequence control logic 3, the sequence control logic 3 sends corresponding sequence control signals to the signal edge generating device 4, which thereupon supplies the corresponding edges as test signals TS to the component 6 to be tested (step S5).

To summarize, the present invention thus provides a method and an apparatus which generates test signals, the frequency of the sequence of pairs of rising and falling signal edges lying above a limiting frequency of the test signal generator used. This makes it possible to use, for example, memory test systems for memory chips whose command sequence frequencies lie above the limiting frequency.

1. Method for the generation of test signals by means of a test signal generator to a component to be tested, the test signal generator generating rising and falling signal edges which are in each case assigned to successive time windows with predetermined time durations, having the following method steps of:
(a) determining a command sequence frequency of as the component to be tested;
(b1) allocating instants for rising signal edges and allocating instants for falling signal edges for the successive time windows, the instants for the rising or falling signal edges that are allocated to a respective time window being allocated in each case into the time range of the time window if the command sequence frequency is lower than a limiting frequency of the test signal generator, the said limiting frequency being determined by the predetermined time duration, or
(b2) allocating at least one instant for a rising signal edge and allocating at least one instant for a falling signal edge for the successive time windows, at least one allocated instant for a rising or falling signal edge being allocated into a time range of one of the following time windows if the command sequence frequency is higher than the limiting frequency of the test signal generator.
(c) generating the test signal with the respective signal edges at the allocated instants and applying the corresponding test signal to the component to be tested.

2. Method according to claim 1, wherein the instants for the signal edges which are assigned to a first number of successive time windows are allocated such that the instants lie in a time range of a second number of successive time windows which follows the first number of time windows.

3. Method according to claim 1, wherein method step (b1) comprises the substeps:
(b1) defining a respective reference instant for each time window;
(b2.2) defining a delay time;
(b2.3) selecting a number N of successive time windows;
(b2.4) allocating the instants of the rising signal edges, which are assigned to the selected number of successive time windows, the instant for the rising signal edge assigned to the K-th time window in each case being positively shifted by a delay time ΔT relative to the respective reference instant of the K-th time window.

4. Method according to claim 3, wherein the selected delay time ΔT is the difference between the corresponding periods of the limiting frequency and the command sequence frequency.

5. Method according to claim 3, wherein, before the N selected time windows, provision is made of a preceding time window which is assigned a rising signal edge, the instant allocated to the rising signal edge corresponding to the reference instant of the preceding time window.

6. Method according to claim 3, wherein an N+1-th time window is provided, which is assigned a rising signal edge, the instant allocated to the rising signal edge corresponding to the reference instant of the N+1-th time window.

7. Method according to claim 3, wherein the reference instant in each case lies in the centre of the time range of the respective time window.

8. Method according to claim 1, wherein at least N=4 successive time windows are selected.

9. Method according to claim 1, wherein the instants of the falling signal edges are allocated such that a rising and a falling signal edge which are assigned to the same time window in each case succeed one another.

10. Method according to claim 1, wherein the time windows are arranged periodically.

11. Method according to claim 1, wherein the time duration of the time windows is at least 4 ns.

12. Method according to claim 1, wherein the test signal generator is a memory tester.

13. Method according to claim 1, wherein the method is carried out in parallel for the generation of a plurality of test signals.

14. Test system for carrying out the method according to claim 1, having:
(a) a clock generator for generating an internal clock signal;
(b) a signal edge generating device for generating rising and falling signal edges in a manner dependent on sequence control signals and for coupling into a component to be tested;
(c) sequence control logic for generating the sequence control signals, which is clocked by the internal clock signal;
(d) evaluation logic for reading out and evaluating signals of the component to be tested.

15. Test system according to claim 14, wherein the component to be tested is a memory component.

16. Test system according to claim 14, wherein the sequence control logic is programmable.
